(19) United States
(12) Patent Application Publication
(10) Pub. No.: US 2023/0113961 A1
(43) Pub. Date: Apr. 13, 2023

(54) OVERHANG REDUCTION USING PULSED BIAS

(71) Applicant: Applied Materials, Inc., Santa Clara, CA (US)

(72) Inventors: Bencherki Mebarki, Santa Clara, CA (US); Komal S. Garde, Santa Clara, CA (US); Kishor Kalathiparambil, San Jose, CA (US); Joung Joo Lee, San Jose, CA (US); Xianmin Tang, San Jose, CA (US)

(73) Assignee: Applied Materials, Inc., Santa Clara, CA (US)

(21) Appl. No.: 18/081,276

(22) Filed: Dec. 14, 2022

Related U.S. Application Data
(63) Continuation-in-part of application No. 16/902,918, filed on Jun. 16, 2020, now abandoned.

(51) Int. Cl. C23C 14/34; H01J 37/34; H01J 37/32; C23C 14/14; C23F 4/00; C23C 14/54

(52) U.S. Cl. CPC C23C 14/3492; H01J 37/3426; H01J 37/32146; H01J 37/347; C23C 14/14; C23F 4/00; C23C 14/542; H01J 2237/332

(57) ABSTRACT

Embodiments of the disclosure relate to methods for enlarging the opening width of substrate features by reducing the overhang of deposited films. Some embodiments of the disclosure utilize a high power bias pulse to etch the deposited film near the opening of the substrate feature. Some embodiments of the disclosure etch the deposited film without damaging the underlying substrate.

### CROSS-REFERENCE TO RELATED APPLICATIONS

This application is a continuation-in-part application of U.S. application Ser. No. 16/902,918, filed Jun. 16, 2020, the entire disclosure of which is incorporated by reference herein in its entirety.

### TECHNICAL FIELD

Embodiments of the disclosure generally relate to methods of physical vapor deposition. In particular, embodiments of the disclosure relate to method to reduce overhang and improve opening width for PVD films deposited within a feature.

### BACKGROUND

The miniaturization of semiconductor circuit elements has reached a point where feature sizes of 45 nm, 32 nm, 28 nm, 20 nm and even less are fabricated on a commercial scale. As the dimensions continue to get smaller, new challenges arise for process steps like filling a gap between circuit elements. As the width between the elements continues to shrink, the gap between them often gets taller and narrower, making the gap more difficult to fill without the gapfill material creating voids and weak seams.

Sputtering, alternatively called physical vapor deposition (PVD), is used for the deposition of metals and other materials in the fabrication of semiconductor integrated circuits. Use of sputtering has been extended to depositing material layers onto the sidewalls of high aspect-ratio holes or gaps such as vias or other vertical interconnect structures.

PVD techniques often experience an overgrowth or overhang of material at the top of the gap before it has been completely filled. This overhang can create a void or seam in the gap where the deposited material has been cut off by the overhang; a problem sometimes referred to as breadloafing.

Current methods of reducing overhang utilize a continuous wave (CW) bias applied to the substrate. But these methods have a limited power range. Further, CW bias can cause damage to the underlying substrate when operated at high power levels.

Accordingly, there is a need for methods of physical vapor deposition which prevents or eliminates the formation of overhang at the top of substrate features or gaps without damaging the underlying substrate.

### SUMMARY

One or more embodiments of the disclosure are directed to a method of physical vapor deposition. The method comprises sputtering a material target in a physical vapor deposition (PVD) chamber to form a material layer on a substrate surface. The substrate surface comprises a feature extending a depth from a top surface to a bottom surface; the feature having an opening width at the substrate surface defined by two sidewalls. The material layer has a greater lateral thickness at the top surface than a lateral thickness on one of the two sidewalls. An additional material layer is deposited on the substrate surface by biasing the substrate surface with an RF bias at a low power. The material layer is etched from the substrate surface by biasing the substrate surface with an RF bias at a high power. The low power and the high power are repeatedly alternated between at a predetermined frequency to reduce the difference between the lateral thickness at the top surface and the lateral thickness on the sidewall.

Additional embodiments of the disclosure are directed to a method of overhang reduction. The method comprises biasing a substrate comprising a material layer with a RF bias within a physical vapor deposition (PVD) chamber with a material target. The substrate comprises a feature extending a depth from the substrate surface to a bottom surface; the feature has an opening width at the substrate surface defined by a first sidewall and a second sidewall. The material layer has a greater lateral thickness at the substrate surface than within the feature. A low power RF bias and a high power RF bias are repeatedly alternated between at a predetermined frequency to reduce the difference between the lateral thickness at the substrate surface and the lateral thickness within the feature.

Further embodiments of the disclosure are directed to a method of depositing a copper liner. The method comprises sputtering a copper target in a physical vapor deposition (PVD) chamber to form a copper layer on a substrate surface. The substrate surface comprises a feature extending a depth from the substrate surface to a bottom surface; the feature has an opening width at the substrate surface defined by a first sidewall and a second sidewall. The copper layer has a greater lateral thickness at the substrate surface than within the feature. An additional copper layer is deposited on the substrate surface by biasing the substrate surface with an RF bias at a low power in a range of about 50 W to about 100 W. The copper layer is etched from the substrate surface by biasing the substrate surface with an RF bias at a high power in a range of about 1000 W to about 1500 W. The low power and the high power repeatedly are alternated between at a predetermined frequency of about 1 kHz to reduce a difference between the lateral thickness at the substrate surface and the lateral thickness within the feature.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross-sectional view of an exemplary substrate with a feature according to one or more embodiment of the disclosure;

FIG. 2 illustrates an exemplary flow chart for a processing method according to one or more embodiment of the disclosure;

FIG. 3 illustrates a cross-sectional view of an exemplary substrate with a material layer thereon having an overhang according to one or more embodiment of the disclosure;

FIG. 4 illustrates a waveform diagram for a RF bias applied to the substrate according to one or more embodiment of the disclosure;

FIG. 5 illustrates a cross-sectional view of an exemplary substrate with a material layer thereon having a reduced overhang according to one or more embodiment of the disclosure; and

FIG. 6 illustrates a schematic cross-sectional view of a physical vapor deposition (PVD) chamber in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments of the disclosure are directed to methods for reducing overhang formed by physical vapor deposition. Some embodiments of the disclosure advantageously provide deposition-etch cycles which remove overhang without damaging the underlying substrate. Some embodiments of the disclosure advantageously facilitate subsequent metallization by providing larger feature openings.

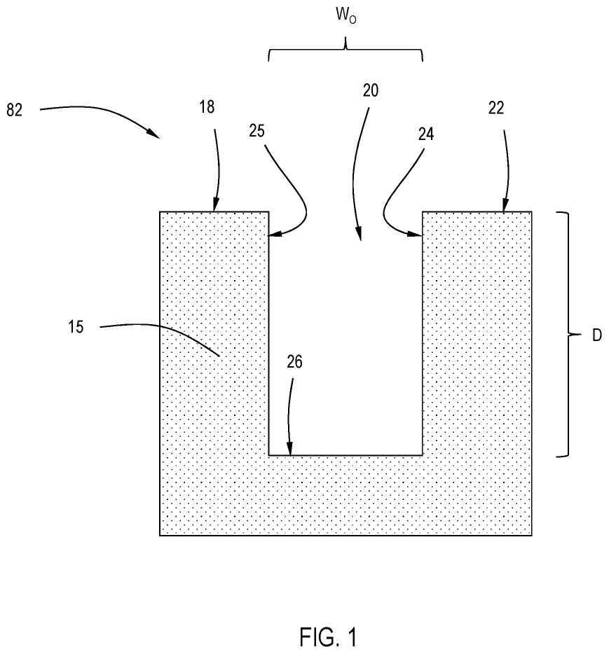

An exemplary substrate 82 for processing according to one or more embodiment is shown in FIG. 1. In some embodiments, the substrate 82 comprises a base material 15 with an exposed surface, also referred to as the substrate surface 18. The substrate surface 18 comprises a feature 20 extending a depth D from a top surface 22 to a bottom surface 26. The feature has an opening width W_{O} defined by a first sidewall 24 and a second sidewall 25. In some embodiments, the first sidewall 24 and the second sidewall 25 are opposite faces of a continuous sidewall (e.g., a circular via).

In some embodiments, the opening width W_{O} is in a range of about 8 nm to about 25 nm or in a range of about 10 nm to about 20 nm. In some embodiments, the opening width W_{O} is about 10 nm, about 14 nm, about 16 nm, about 20 nm or about 22 nm.

In some embodiments, the base material 15 comprises a dielectric. In some embodiments, the base material 15 comprises one or more of silicon nitride, silicon oxynitride, silicon carbonitride, silicon oxide or silicon oxycarbide. In some embodiments, the base material 15 consists essentially of silicon oxide. As used in this regard, a material which consists essentially of a stated material comprises greater than or equal to about 95%, greater than or equal to about 98%, greater than or equal to about 99% or greater than or equal to about 99.5% of the stated material on a molar basis.

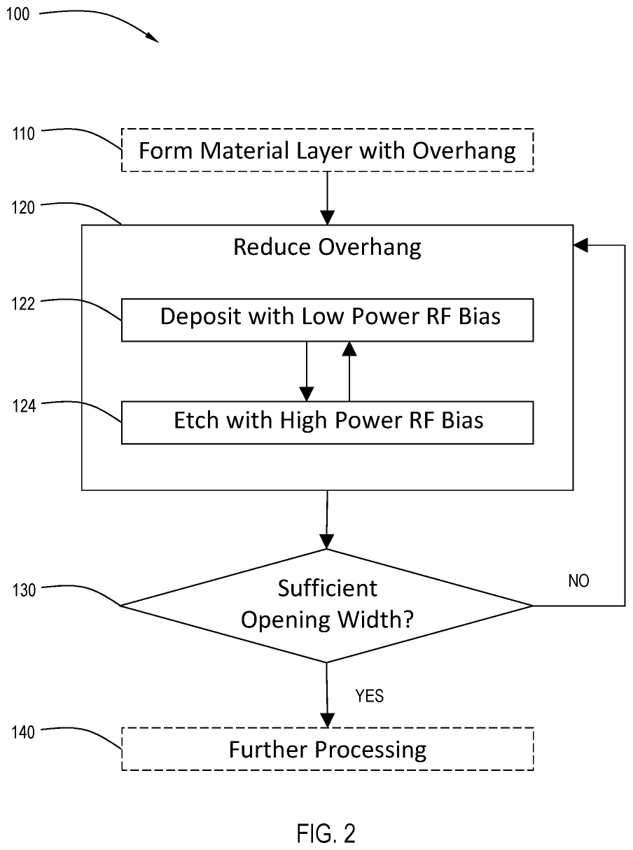

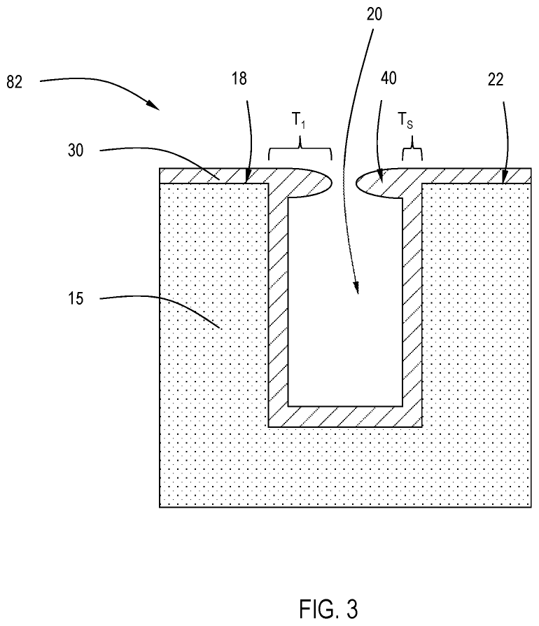

Referring to FIGS. 2 and 3, an exemplary method 100 for processing a substrate 82 begins with optional operation 110 where a material target in a physical vapor deposition (PVD) chamber is sputtered to form a material layer 30 with an overhang 40 on the substrate surface 18. The material layer 30 has a greater lateral thickness T₁ at the top surface 22 of the feature 20 than an average thickness T_{S} on a sidewall 24 within the feature 20. The difference between T₁ and T_{S} is referred to as the overhang width 40. The opening W_{O} of the feature at the top surface 22 of the feature 20 is less than the width of the feature between the sidewalls 24, 25 with the material layer 30 deposited thereon.

In some embodiments, the sputtering process forms a material layer 30 with a thickness on the substrate surface 18 outside of the feature 20 in a range of about 10 nm to about 20 nm or in a range of about 12 nm to about 18 nm. In some embodiments, the sputtering process forms a material layer 30 with a thickness on the substrate surface 18 outside of the feature 20 of about 15 nm.

The material target and the material layer 30 comprise the same material. In some embodiments, the material comprises a conductor. In some embodiments, the material comprises one or more of copper, tungsten, cobalt, ruthenium, molybdenum, indium, iridium or rhodium. In some embodiments, the material comprises a dielectric. In some embodiments, the material comprises one or more of titanium nitride, tantalum nitride, ruthenium nitride, aluminum nitride, silicon oxide, aluminum oxide or aluminum oxynitride.

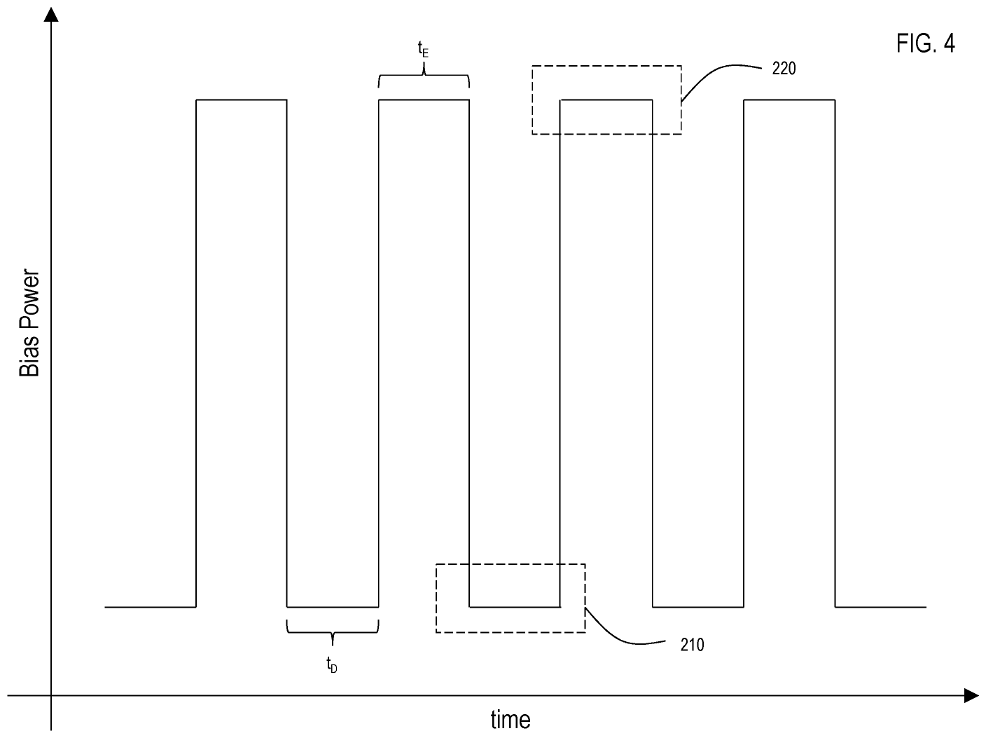

The method 100 continues by reducing the overhang 40 by a deposition-etch cycle, also referred to as a dep-etch cycle 120. The dep-etch cycle 120 comprises one deposition phase 122 and one etch phase 124. While deposition phase 122 is shown in FIGS. 2 and 4 to precede etch phase 124, the skilled artisan will understand that this order is not limiting and either phase can be performed first during any dep-etch cycle 120. The dep-etch cycle 120 may begin with either the deposition phase 122 or the etch phase 124.

The deposition phase 122 deposits additional material layer 30 on the substrate surface 18 by biasing the substrate surface 18 with a RF bias at a low power. In some embodiments, the low power is in a range of about 10 W to about 100 W, in a range of about 20 W to about 100 W. in a range of about 50 W to about 100 W or in a range of about 50 W to about 75 W. In some embodiments, the low energy is about 70 W.

The etch phase 124 etches the material layer 30 from the substrate surface 18 by biasing the substrate surface 18 with a RF bias at a high power. In some embodiments, the high power is in a range of about 200 W to about 3000 W, in a range of about 500 W to about 2500 W or in a range of about 1000 W to about 2000 W. In some embodiments, the high energy is about 1400 W.

Without being bound by theory, it is believed that the high power RF bias cannot be applied to the substrate surface 18 for an extended period of time. If the high power RF bias is applied for too long, the base material 15 may be damaged by the RF bias or the energy may arc from the substrate to other portions of the processing chamber. Accordingly, the inventors have surprisingly found that by using short bursts of a high power RF bias and low power RF bias the material layer 30 may be etched without damage to the underlying base material 15. In some embodiments, the substrate is substantially undamaged. Damage to the substrate may be physically evaluated in the case of physical layer damage (separation of layers, adhesion); evaluated by TEM for structural damage; evaluated by EELS analysis for chemical damage; or evaluated by electrical analysis for integration damage.

During the dep-etch cycle 120, the deposition phase 122 and the etch phase 124 are repeated in an alternating fashion. In some embodiments, the time between the deposition phase 122 and the etch phase 124 is minimized. FIG. 4 illustrates a waveform 200 of the bias power over time during the dep-etch cycle 120. The deposition phase 122 is shown at a low power in region 210 with period t_{D}. The etch phase 124 is shown at a high energy in region 220 with period t_{E}.

The waveform 200 illustrated in FIG. 4 is distinct from a continuous wave (CW) waveform. In a CW waveform the bias power gently increases and decreases to form a sine-type wave with peaks and troughs at the high energy and low energy. The inventors have found that a CW-type bias waveform has a much lower maximum (high power bias) that can be applied to the substrate surface 18 without damaging the base material 15. In contrast, the waveform 200 of the present invention quickly transitions from the low power bias in region 210 to the high power bias in region 220.

The frequency of the bias power is controlled. In some embodiments, the frequency is in a range of about 1 Hz to about 10 kHz or in a range of about 100 Hz to about 5 kHz. In some embodiments, the frequency is about 1 kHz.

The duty cycle is the time percentage of a cycle spent applying the high energy bias to the substrate surface. In some embodiments, the duty cycle is in a range of about 5% to about 95%, in a range of about 10% to about 90%, in a range of about 20% to about 80%, in a range of about 30% to about 70%, in a range of about 40% to about 60% or in a range of about 45% to about 55%. In some embodiments, the duty cycle is about 50%.

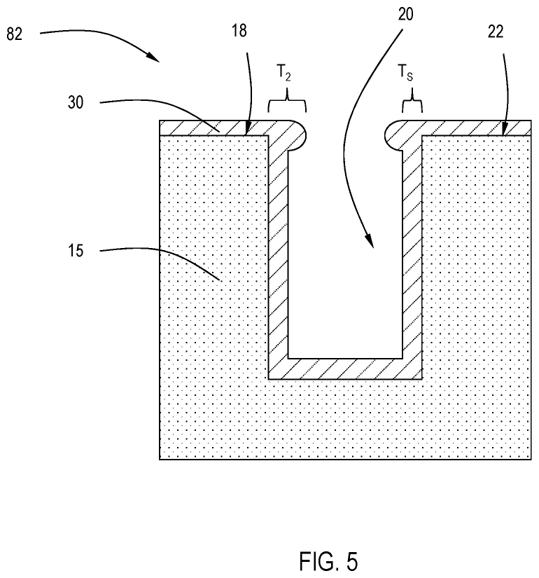

The dep-etch cycle 120 is repeated until a sufficient thickness of the overhang 40 has been removed. As illustrated in FIG. 5, after a plurality of dep-etch cycles, a substrate 82 has a material layer 30 with a reduced overhang 40. Stated differently, the difference between the reduced lateral thickness T₂ at the top 22 of the feature 20 and thickness T_{S} on the sidewall 24 within the featured 20 is reduced. In some embodiments, the thickness T_{S} within the feature is substantially unchanged by the dep-etch cycle 120. In some embodiments, the thickness T_{S} within the feature is increased by the dep-etch cycle 120.

In some embodiments, the dep-etch cycle 120 deposits additional material layer on the substrate surface 18 outside of the feature 20. In some embodiments, the dep-etch cycle 120 deposits greater than or equal to about 2 nm, greater than or equal to about 4 nm, greater than or equal to about 6 nm, or greater than or equal to about 8 nm on the substrate surface 18 outside of the feature. In some embodiments, the dep-etch cycle 120 deposits about 6 nm of material layer on the substrate surface 18 outside of the feature 20.

At decision point 130, it is determined if the opening width W_{O} of the feature 20 is sufficient. If the opening width W_{O} is not sufficient, the method 100 returns to perform additional dep-etch cycles 120. If the opening width W_{O} is sufficient the substrate may undergo further processing at operation 140.

In some embodiments, the further processing at operation 140 comprises depositing a conductive fill material within the feature 20. In some embodiments, the conductive fill material comprises a different material than the material layer 30. In some embodiments, the conductive fill material comprises a metal or metal alloy. In some embodiments, the conductive fill material comprises one or more of copper, tungsten, cobalt, ruthenium, molybdenum, indium, iridium, or rhodium.

In some embodiments, the opening width W_{O} of the feature 20 is in a range of about 10 nm to about 20 nm before sputtering the material target, sputtering the material target forms a material layer 30 with a thickness of about 15 nm on the substrate surface 18 outside of the feature 20, and repeatedly alternating between the low energy and the high energy forms an additional material layer with a thickness of about 6 nm on the substrate surface 18 outside of the feature 20. In this embodiment, the opening width of the feature 20 is greater than or equal to about 7 nm after sputtering the material target and performing a plurality of dep-etch cycles 120.

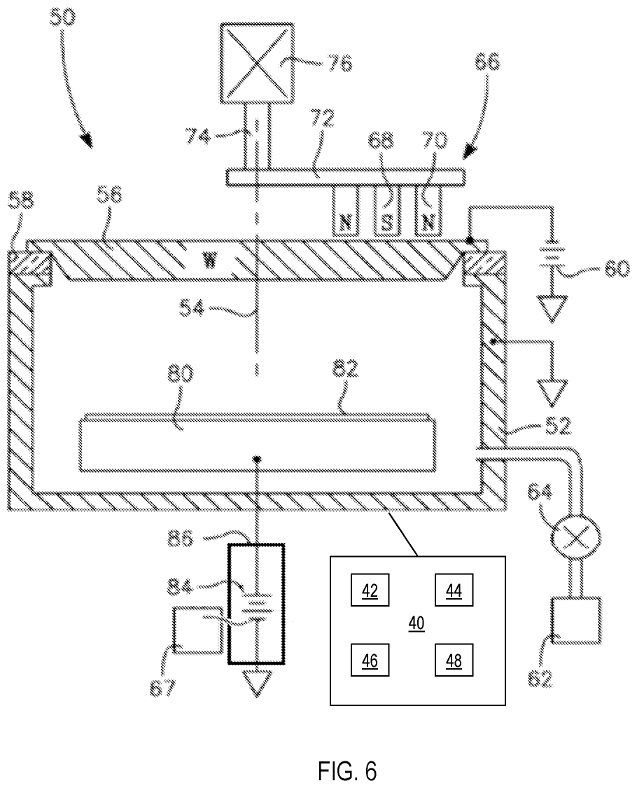

An exemplary physical vapor deposition chamber 50, useful for the methods of one or more embodiment, is illustrated in FIG. 6. The physical vapor deposition chamber 50 includes a vacuum chamber 52 arranged about a central axis 54 on which a target 56 is supported through an isolator 58, which vacuum seals the target 56 to the vacuum chamber 52 and electrically isolates the target 56 from the electrically grounded vacuum chamber 52. A vacuum pump system (not shown) pumps the interior of the vacuum chamber 52 to a pressure in the low milliTorr range.

In one or more embodiments, the shape of the front surface of the target 56 can be planar or generally concave with thicker outer peripheral edges than inner diameter portions. The target 56 includes a layer of material facing the interior of the vacuum chamber 52 and which typically contains no more than 5 atomic % of elements other than the material to be deposited to provide a source of sputtered material.

A DC power source 60 negatively biases the target with respect to the grounded vacuum chamber 52 or grounded sidewall shield (not shown) to excite a plasma gas into a plasma. In some embodiments, the plasma gas is supplied in the vacuum chamber 52 from a gas source 62 through a mass flow controller 64.

In one or more embodiments, the plasma gas comprises one or more of helium (He), neon (Ne), argon (Ar), krypton (Kr), and xenon (Xe). In some embodiments, the plasma gas comprises one or more of helium (He), neon (Ne), or argon (Ar).

In one or more embodiments, the target power supplied by the DC power source 60 excites the plasma processing gas into a plasma and positively charged ions of the plasma are accelerated towards the target 56 and sputter material from the target 56. The density of the plasma is increased by placing in back of the target 56 a magnetron 66 having an inner magnetic pole 68 of one magnetic polarity surrounded by an outer magnetic pole 70 of the opposed magnetic polarity. The poles 68, 70 project a magnetic field into the vacuum chamber 52 parallel to the face of the target 56 to trap electrons and hence increase the plasma density and the resultant sputtering rate. To improve the sputtering uniformity and target utilization, the magnetic poles 68, 70 are asymmetric about the central axis 54 but supported on an arm 72 connected to a shaft 74 extending along the central axis 54. A motor 76 rotates the shaft 74 and hence the magnetron 66 about the central axis 54 to provide at least azimuthal uniformity.

A pedestal 80 within the vacuum chamber 52 supports a substrate 82 in opposition to the target 56 to be coated with the material sputtered from the target 56. A signal generator 86 includes a RF power source 84 and a waveform generator 67 to bias the pedestal 80. The pedestal 80 is conductive so that it acts as an electrode. The RF bias in the presence of a plasma within the vacuum chamber 52 causes a negative DC self-bias to develop on the pedestal 80 so that sputtered metal ions are accelerated towards the substrate 82 and their trajectories enter deep within any high aspect-ratio holes or features formed in the substrate 82.

Operation of the physical vapor deposition chamber 50 is controlled by a controller 640. The controller 640 is coupled to one or more of the motor 76, the DC power source 60, the signal generator 86, or the mass flow controller 64. In some embodiments, there are more than one controller 640 connected to the individual components and a primary control processor is coupled to each of the separate processors to control the physical vapor deposition chamber 50. The controller 40 may be one of any form of general-purpose computer processor, microcontroller, microprocessor, etc., that can be used in an industrial setting for controlling various chambers and sub-processors.

The at least one controller 640 can have a processor 642, a memory 644 coupled to the processor 642, input/output devices 646 coupled to the processor 642, and support circuits 648 for communication between the different electronic components. The memory 644 can include one or more of transitory memory (e.g., random access memory) and non-transitory memory (e.g., storage).

The memory 644, or computer-readable medium, of the processor may be one or more of readily available memory such as random access memory (RAM), read-only memory (ROM), floppy disk, hard disk, or any other form of digital storage, local or remote. The memory 644 can retain an instruction set that is operable by the processor 642 to control parameters and components of the physical vapor deposition chamber 50. The support circuits 648 are coupled to the processor 642 for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 40 has one or more configurations to execute individual processes or sub-processes to perform the disclosed method 100. The controller 640 can be connected to and configured to operate intermediate components to perform the functions of method 100. For example, the controller 640 can be connected to and configured to control one or more of gas valves, actuators, motors, slit valves, vacuum control, etc.

The controller 640 of some embodiments has one or more configurations selected from: a configuration to rotate shaft 74; a configuration to bias the target 56; a configuration to bias the substrate 82; a configuration to apply a waveform to the substrate bias; or a configuration to control the flow of the plasma gas.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of physical vapor deposition, the method comprising:
sputtering a material target in a physical vapor deposition (PVD) chamber to form a material layer on a substrate surface comprising a feature extending a depth from a top surface to a bottom surface, the feature having an opening width at the substrate surface defined by two sidewalls, the material layer having a greater lateral thickness at the top surface than a lateral thickness on one of the two sidewalls;
depositing additional material layer on the substrate surface by biasing the substrate surface with an RF bias at a low power;
etching the material layer from the substrate surface by biasing the substrate surface with an RF bias at a high power; and
repeatedly alternating between the low power and the high power at a predetermined frequency to reduce the difference between the lateral thickness at the top surface and the lateral thickness on the sidewall.

2. The method of claim 1, wherein the substrate is substantially undamaged.

3. The method of claim 2, wherein the duty cycle of the high power RF bias is about 50%.

4. The method of claim 1, wherein the material target comprises copper.

5. The method of claim 1, wherein the low power is in a range of about 50 W to about 100 W.

6. The method of claim 1, wherein the high power is in a range of about 1000 W to about 3000 W.

7. The method of claim 1, wherein the predetermined frequency is in a range of about 1 Hz to about 10 kHz.

8. The method of claim 1, wherein sputtering the material target forms a material layer with a thickness of about 15 nm on the substrate surface.

9. The method of claim 1, wherein repeatedly alternating between the low power and the high power forms a material layer with a thickness of about 6 nm on the substrate surface.

10. The method of claim 1, wherein the opening width of the feature is in a range of about 10 nm to about 20 nm before sputtering the material target.

11. The method of claim 1, wherein:
the opening width of the feature is in a range of about 10 nm to about 20 nm before sputtering the material target;
sputtering the material target results in a material layer with a thickness of about 15 nm on the substrate surface;
repeatedly alternating between the low power and the high power forms a material layer with a thickness of about 6 nm on the substrate surface; and
the opening width of the feature is greater than or equal to about 7 nm after sputtering the material target and repeatedly alternating between the low power and the high power.

12. The method of claim 1, further comprising depositing a conductive fill material within the feature after reducing the difference between the lateral thickness at the top surface and the lateral thickness on the sidewall.

13. A method of overhang reduction, the method comprising:
biasing a substrate comprising a material layer with a RF bias within a physical vapor deposition (PVD) chamber with a material target, the substrate comprising a feature extending a depth from the substrate surface to a bottom surface, the feature having an opening width at the substrate surface defined by a first sidewall and a second sidewall, the material layer having a greater lateral thickness at the substrate surface than within the feature; and
repeatedly alternating between a low power RF bias and a high power RF bias at a predetermined frequency to reduce the difference between the lateral thickness at the substrate surface and the lateral thickness within the feature.

14. The method of claim 13, wherein the substrate is substantially undamaged by biasing the substrate and alternating between a low power RF bias and a high power RF bias.

15. The method of claim 14, wherein the duty cycle of the high power RF bias is about 50%.

16. The method of claim 13, wherein the material layer comprises copper.

17. The method of claim 13, wherein the low power RF bias is in a range of about 50 W to about 100 W.

18. The method of claim 13, wherein the high power RF bias is in a range of about 1000 W to about 3000 W.

19. The method of claim 13, wherein the predetermined frequency is in a range of about 1 Hz to about 10 kHz.

20. A method of depositing a copper liner, the method comprising:
sputtering a copper target in a physical vapor deposition (PVD) chamber to form a copper layer on a substrate surface comprising a feature extending a depth from the substrate surface to a bottom surface, the feature having an opening width at the substrate surface defined by a first sidewall and a second sidewall, the copper layer having a greater lateral thickness at the substrate surface than within the feature;
depositing additional copper layer on the substrate surface by biasing the substrate surface with an RF bias at a low power in a range of about 50 W to about 100 W;
etching the copper layer from the substrate surface by biasing the substrate surface with an RF bias at a high power in a range of about 1000 W to about 1500 W; and
repeatedly alternating between the low power and the high power at a predetermined frequency of about 1 kHz to reduce a difference between the lateral thickness at the substrate surface and the lateral thickness within the feature.
